(19) United States
(12) Patent Application Publication
(10) Pub. No.: US 2025/0343558 A1
(43) Pub. Date: Nov. 6, 2025

(54) METHOD AND CIRCUIT FOR DETECTING AND CORRECTING BINARY DIGIT ERRORS

(71) Applicant: WEIDONG ZHANG, SAN RAMON, CA (US)

(72) Inventor: WEIDONG ZHANG, SAN RAMON, CA (US)

(21) Appl. No.: 19/270,464

(22) Filed: Jul. 15, 2025

(51) Int. Cl. H03M 13/11

(52) U.S. Cl. CPC H03M 13/11

(57) ABSTRACT

This invention details the Error Index Code (EIC) method and circuit designed to correct single-bit errors and detect double-bit errors during data transmission, processing, and storage. The EIC offers a scalable error correction solution with improved performance compared to Hamming code. Its hierarchical and modularized architecture simplifies data signal routing, minimizes latency, and enables predictable timing—providing an ideal ECC solution for high bandwidth applications.

### CROSS REFERENCE TO RELATED APPLICATIONS

This patent application claims priority to U.S. Provisional Patent Application No. ______, entitled “METHOD AND CIRCUIT FOR DETECTING AND CORRECTING BINARY DIGIT ERRORS”, filed ______, which is incorporated herein by reference for all purposes.

### BACKGROUND OF THE INVENTION

### 1. Field of the Invention

The present invention relates to methods and circuits for identifying and rectifying binary digit errors encountered in data transmission, processing and storage systems. Specifically, an aspect of this invention utilizes an Error Index Code (EIC) as a mechanism for detecting and correcting individual bit errors within digital data.

### 2. Discussion of the Related Art

Data errors can occur during transmission, processing, and storage due to electrical noise or physical failures. The occurrence of even a single bit error can result in significant consequences, including data loss, system instability, or disruption of critical services. Consequently, technical solutions for ensuring data integrity are essential. A common approach involves incorporating redundancy bits into the data stream; these bits facilitate detection and correction of errors that may arise during data transmission, processing or storage.

Error Correction Codes (ECCs) are a type of redundancy code widely employed in the electronics industry for detecting and correcting bit errors. The first ECC algorithm, known as the Hamming code, was invented by the American mathematician Richard Hamming in 1950. Hamming codes are single-error correcting and double-error detecting (SECDED). Subsequently, in 1959, the French mathematician Alexis Hocquenghem, and independently in 1960, the American mathematicians Raj Chandra Bose and D. K. Ray-Chaudhuri, invented the Bose-Chaudhuri-Hocquenghem (BCH) codes. BCH codes offer the capability to detect and correct multiple-bit errors. To achieve this enhanced error correction capability, a higher number of redundancy bits are incorporated into the primary data stream. This, however, results in a trade-off: a reduced code rate. The code rate refers to the ratio between the number of primary data bits and the total number of bits (primary data bits plus redundancy bits). Numerous error correcting codes exist beyond those based on Hamming and BCH methodologies; a comprehensive overview is accessible via the “List of error-correcting codes” section of the Wikipedia article located at https://en.wikipedia.org/wiki/Error_correction_code.

Despite theoretical susceptibility to data errors within modern digital devices, empirical analysis demonstrates their statistically infrequent occurrence. A study conducted by Bianca S., Eduardo P., and Wolf-Dietrich W. (University of Toronto & Google Inc.) assessed DRAM error rates across a deployed fleet of commodity servers over a 2.5-year period. The analysis indicated DRAM error frequencies ranging from 25,000 to 70,000 errors per billion device hours per million bits-equivalent to approximately 0.68×10⁻¹⁸ to 1.90×10⁻¹⁸ errors per DRAM access cycle (100 nanoseconds) per kilobit. Consequently, the single-error correction methodology utilizing the Hamming Code (characterized by its highest code rate) provides a demonstrably efficient and effective solution compared to alternative Error Correction Codes (ECC), supported by widespread implementation in computer memory systems, modems, and satellite communication infrastructure.

Despite offering a robust and efficient error correction mechanism, the Hamming code exhibits inherent limitations regarding scalability. The core challenge arises from its architecture, which intersperses redundancy bits with primary data bits in a fixed pattern-specifically, assigning redundancy bits to positions corresponding to powers of two while primary data occupies the remaining positions. This asymmetrical bit allocation fundamentally restricts the development of hierarchical and modularized Hamming code algorithms. Consequently, circuit implementations for encoding, error detection, and correction are intrinsically tied to the length of the primary data stream, thereby limiting their reusability for larger data volumes and complicating data signal routing with increased payload sizes. The prevalent (72, 64-bit) Hamming code implementation in DRAM technology is now constrained by these limitations. However, escalating demands in high-performance computing and artificial intelligence—particularly High Bandwidth Memory (HBM) exceeding 1024 bits-necessitate ECC solutions characterized by reduced circuit complexity and predictable delay. As a result, both the memory and artificial intelligence industries require novel ECC approaches to address these evolving demands.

### SUMMARY OF THE INVENTION

Various embodiments herein detail Error Index Code (EIC) methods and circuits designed for detecting and correcting bit errors within digital data transmission, processing, and storage systems.

The (n+1)-bit Error Index Code (EIC) encoder, as implemented according to the present invention, consists of two identical n-bit EIC encoders and ‘n’ instances of two-input XOR gates. When n≥3, each n-bit EIC encoder is recursively constructed from two identical (n−1)-bit EIC encoders and their corresponding ‘n−1’ XOR gates. Each n-bit EIC encoder processes half of the primary data input, generating ‘n’ bits of EIC redundancy data. The resulting (n+1)-bit EIC redundancy data is generated through the following operations: the most significant bit is derived from an XOR operation between the most significant bits of the redundant data produced by the two n-bit EIC encoders; the second most significant bit corresponds directly to the most significant bit of the redundant data generated by the n-bit EIC encoder processing the upper half of the primary data input; and the remaining bits are derived from XOR operations between corresponding index bits of the redundant data generated by the two n-bit EIC encoders.

The 2-bit Error Index Code (EIC) encoder, as implemented according to the present invention, comprises a two-input XOR gate and processes two input bits of primary data. The resulting 2-bit EIC redundancy data is generated through the following operations: the most significant bit is derived from an XOR operation between the two input data bits; and the least significant bit corresponds directly to the most significant bit of the two input data bits.

The Error Index Code (EIC) method processes a 2ⁿ bits primary data stream and generates n+1 bits of redundancy code. The method operates as follows: the most significant bit of the redundancy code is derived from an exclusive OR (XOR) operation applied to all bits of the primary data. For each redundancy bit at index m, where 0≤m≤n−1, the primary data is evenly partitioned into 2^{n-m} sections, sequentially numbered from 0 to 2^{n-m}−1 (right-to-left). The resulting redundancy bit is then generated by performing an exclusive OR (XOR) operation on all bits within the odd-numbered sections of this partition.

The (n+1)-bit Error Index Code (EIC) encoder implements the Error Index Code (EIC) method utilizing a hierarchical and modularized structure. This approach significantly reduces the complexity and challenges associated with data signal routing compared to a flattened implementation.

To detect and correct a potential bit error within the primary data stream, an initial redundancy code is generated utilizing the EIC method and transmitted, processed or stored alongside the primary data. To mitigate potential errors introduced into this initial redundancy code during transmission, processing or storage, a supplementary parity bit is derived from the initial redundancy code's data via XOR operation. This parity bit is concurrently transmitted, processed or stored with both the primary data stream and the initial redundancy code.

To detect and correct a potential bit error within the data stream—encompassing the primary data, the initial redundancy code, and the supplementary parity—verification of the initial redundancy code commences with an assessment of the supplementary parity bit. If an error is detected within the initial redundancy code, the primary data is determined to be error-free. Conversely, if no error is detected in the redundancy code, the EIC Method is re-executed to generate a new redundancy code from the primary data. A subsequent bitwise XOR operation between the initial redundancy code and the newly generated redundancy code produces a result vector. Under conditions of error-free primary data transmission or storage, all bits within the result vector register as ‘0’. A single error in the primary data manifests as a ‘1’ value for the most significant bit of the result vector; the remaining bits directly indicate the index of the erroneous bit, and the corresponding bit in the primary data is inverted. The presence of two errors in the primary data is indicated by a ‘0’ value for the most significant bit of the result vector, and at least one ‘1’ bit within the remaining bits of the result vector. In instances where multiple errors are present within the primary data, the remaining bits of the result vector represent the bitwise XOR of the indices corresponding to all erroneous bits. Upon detection of an error within the initial redundancy code, the initial redundancy code may be superseded by the newly generated redundancy code, and the supplementary parity bit is updated via the XOR operation result applied to the newly generated redundancy code.

The single-error detection and correction circuit implementing an Error Index Code (EIC) methodology, representative of one embodiment of the present invention, comprises at least an (n+1)-bit EIC encoder, a (n+2)-input XOR gate, an n-input decoder, and multiple 2-input XOR gates. The (n+1)-bit EIC encoder processes the primary data inputs to generate new redundancy code signals. The (n+2)-input XOR gate performs a logical XOR operation on the received initial redundancy code signals and the supplementary parity bit signal to detect potential bit errors within the initial redundancy code signals. If an error is detected, the primary data inputs are directly output; otherwise, the 2-input XOR gates perform a bitwise XOR operation between the newly generated redundancy code signals and the received initial redundancy code signals, generating a result vector signal. The most significant bit of this result vector signal indicates the presence of a bit error in the primary data inputs, while the n-input decoder utilizes the remaining bits of the vector signal to generate an error bit index signal. Upon detection of a bit error, the error bit index signal inverts the corresponding bit within the primary data inputs; otherwise, all bits within the primary data inputs are directly output.

Although the present disclosure employs XOR operations, functionally equivalent XNOR operations may be implemented without exceeding the claimed scope of this invention.

These and various other features as well as advantages, which characterize the present invention, will be apparent from a reading of the following detailed description and a review of the associated drawings.

### BRIEF DESCRIPTION OF THE DRAWINGS

Aspects and embodiments of the disclosure will become more apparent from the detailed description set forth below when taken in conjunction with the drawings in which like reference characters identify correspondingly throughout.

FIG. 1 presents a block diagram illustrating an architecture for an (n+1)-bit Error Index Code (EIC) encoder constructed using two n-bit EIC encoders, as exemplified in one embodiment of the present invention.

FIG. 2 presents a block diagram illustrating the structure of a 2-bit EIC encoder as exemplified in one embodiment of the present invention.

FIG. 3 illustrates a block diagram representing the EIC method. The method is configured to generate n+1 redundancy bits from a primary data stream comprising 2ⁿ bits.

FIG. 4 illustrates an example demonstrating the generation of a 6-bit Error Index Code (EIC) for a 32-bit primary data stream. The figure details the subsequent process for identifying the location of a bit error within the data.

FIG. 5 presents a block diagram illustrating a structure of a single-error detection and correction circuit employing Error Index Code (EIC), as exemplified in one embodiment of the present invention.

### DETAILED DESCRIPTION OF THE PREFERRED EMBODIMENTS

This disclosure details the Error Index Code (EIC) method and circuit designed to correct single-bit errors and detect double-bit errors during data transmission, processing, and storage. Compared to the Hamming code, the EIC method generates n+1 redundancy bits for any 2ⁿ bits of primary data. When implemented as an ECC solution within a data transmission, processing or data storage device, according to one embodiment of the present invention, the EIC encoding and decoding circuits are hierarchically constructed using multiple 2-input XOR gates. The architecture facilitates even distribution across the circuit layout, aligning along the data bus direction to substantially reduce data signal routing complexity. Consequently, circuit delay is substantially reduced and becomes predictable, doubling the primary data size results in an increase in delay time equivalent to that of a single 2-input XOR gate. The accompanying figures are referenced throughout this detailed description of the embodiments, where like elements are denoted by consistent reference numbers for clarity. These embodiments provide sufficient detail to allow those skilled in the art to practice the invention; however, it is understood that alternative embodiments may be utilized, and modifications can be made without departing from the scope of this present invention.

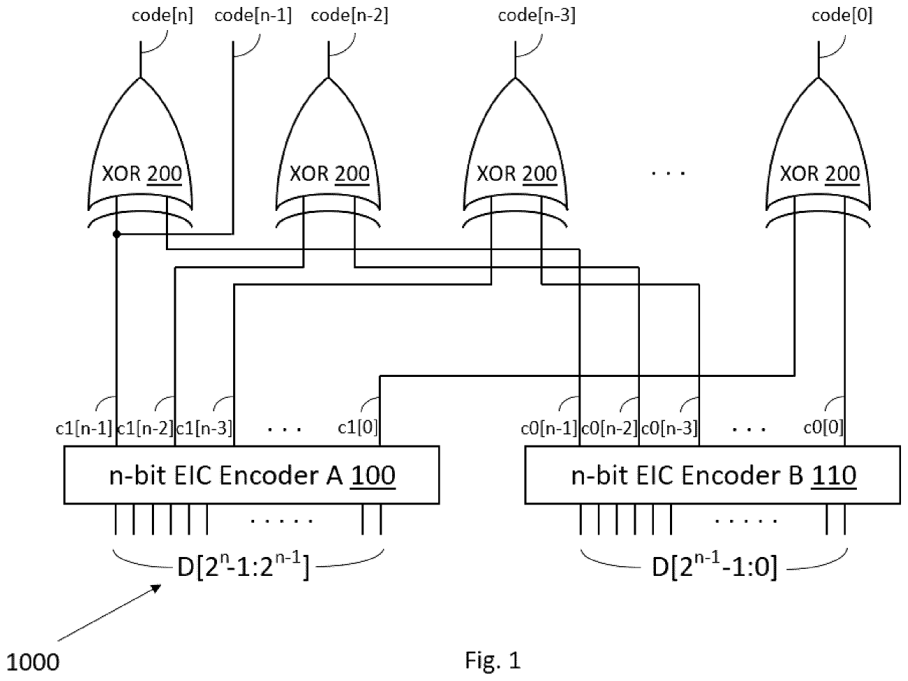

FIG. 1 presents a block diagram (reference numeral 1000) illustrating an architecture for a novel (n+1)-bit Error Index Code (EIC) encoder, implemented according to one embodiment of the present invention using two identical n-bit EIC encoders. This (n+1)-bit encoder comprises an n-bit EIC encoder A (reference numeral 100) and an n-bit EIC encoder B (reference numeral 110), along with n instances of two-input XOR gates (reference numeral 200). The architecture employs a hierarchical design; when n≥3, each n-bit EIC encoder A or B can be recursively constructed from two (n−1)-bit EIC encoders and their corresponding (n−1) XOR gates-mirroring the structure depicted in diagram 1000. Specifically, EIC encoder A processes the upper half of the primary data input D[2ⁿ-1:2ⁿ⁻¹] to generate redundancy bits c1[n-1:0], while EIC encoder B operates on the lower half of the primary data input D[2ⁿ⁻¹-1:0], producing redundancy bits c0[n-1:0]. The XOR gates function as logical exclusive OR circuits. The resulting (n+1)-bit EIC redundancy data, designated code[n:0], is generated as follows: code[n] is the result of an XOR operation between c1[n-1] and c0[n-1], code[n-1] directly corresponds to c1[n-1], and code[i] (for 0≤i≤n−2) is the result of an XOR operation between c1[i] and c0[i].

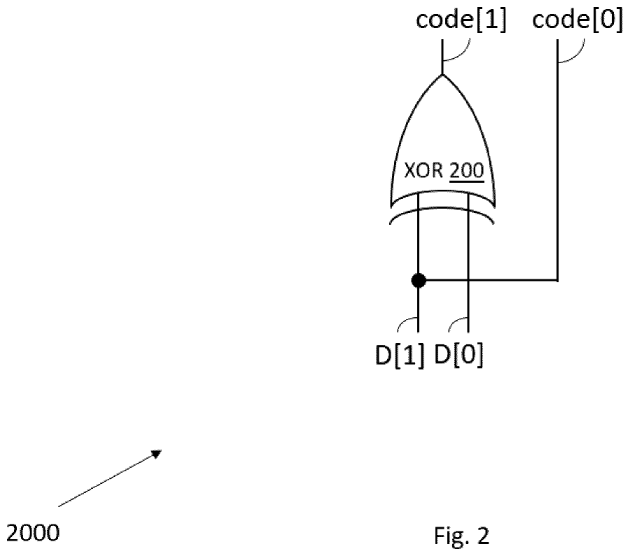

FIG. 2 presents a block diagram (reference numeral 2000) illustrating a representative architecture for a 2-bit Error Index Code (EIC) encoder in accordance with one embodiment of the present invention. The encoder incorporates a 2-input XOR gate (reference numeral 200), which processes two primary data inputs, D[1] and D[0]. This configuration generates redundancy bits, designated code[1:0], wherein code[1] is derived from an exclusive OR operation performed on D[1] and D[0], while code[0] replicates the signal of D[1].

As is standard within the field, FIG. 1 and FIG. 2 illustrate a hierarchical and scalable circuit architecture—designated block diagrams 1000 and 2000 respectively—enabling the construction of any (n+1)-bit Error Index Code (EIC) encoder for primary data streams comprising 2ⁿ bits, where n≥1.

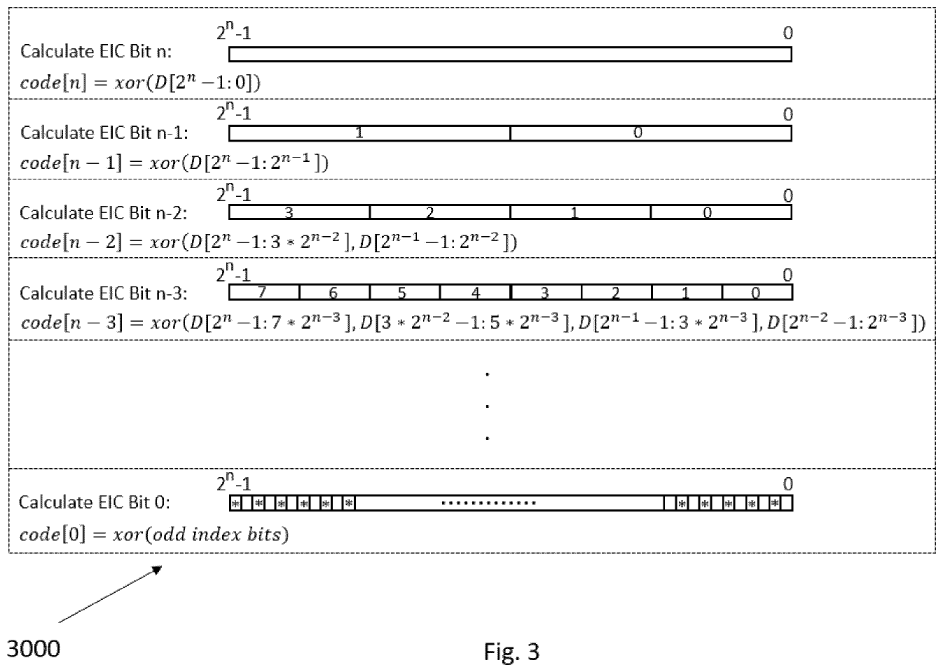

FIG. 3 illustrates an method (reference numeral 3000) for generating n+1 redundancy bits (code[n:0]) for primary data streams comprising 2ⁿ bits (D[2ⁿ-1:0]), where n≥1. The method operates as follows:

For code[n], the resulting redundancy bit is the exclusive OR (XOR) operation applied to all bits of the primary data D[2ⁿ-1:0].

For each redundancy bit code[m], where 0≤m≤n−1, the primary data is evenly partitioned into 2^{n-m} sections, sequentially numbered from 0 to 2^{n-m}−1 (right-to-left), The resulting redundancy bit is then the exclusive OR (XOR) operation applied to all bits within the odd-numbered sections of this partition. For example:

For code[n-1], the primary data is partitioned into 2 sections, and the XOR operation applies to the bits in section 1 (D [2ⁿ-1:2ⁿ⁻¹]), when n≥2.

For code[n-2], the primary data is partitioned into 4 sections, and the XOR operation applies to the bits in sections 3 and 1 (D[2ⁿ—1:3*2ⁿ⁻²] and D[2ⁿ⁻¹-1:2ⁿ⁻²]), when n≥3.

For code[n-3], the primary data is partitioned into 8 sections, and the XOR operation applies to the bits in sections 7, 5, 3, and 1 (D[2ⁿ-1:7*2ⁿ⁻³], D[3*2ⁿ⁻²-1:5*2ⁿ⁻³], D[2ⁿ⁻¹-1:3*2ⁿ⁻³] and D[2ⁿ⁻²-1:2ⁿ⁻³]), when n≥4.

Finally, for code[0], the entire 2ⁿ bit primary data stream is partitioned into 2ⁿ sections, and the XOR operation applies to all odd-indexed bits.

The Error Index Code (EIC) encoder, as illustrated in diagram 1000 of FIG. 1, implements the method utilizing a hierarchical and modularized structure. This approach significantly reduces the complexity and challenges associated with data signal routing compared to a flattened implementation.

As is known to those skilled in the art, when defining bit indices in reversed sequence, the XOR operation will be applied to even-numbered sections of the partition, consistent with the scope of this invention.

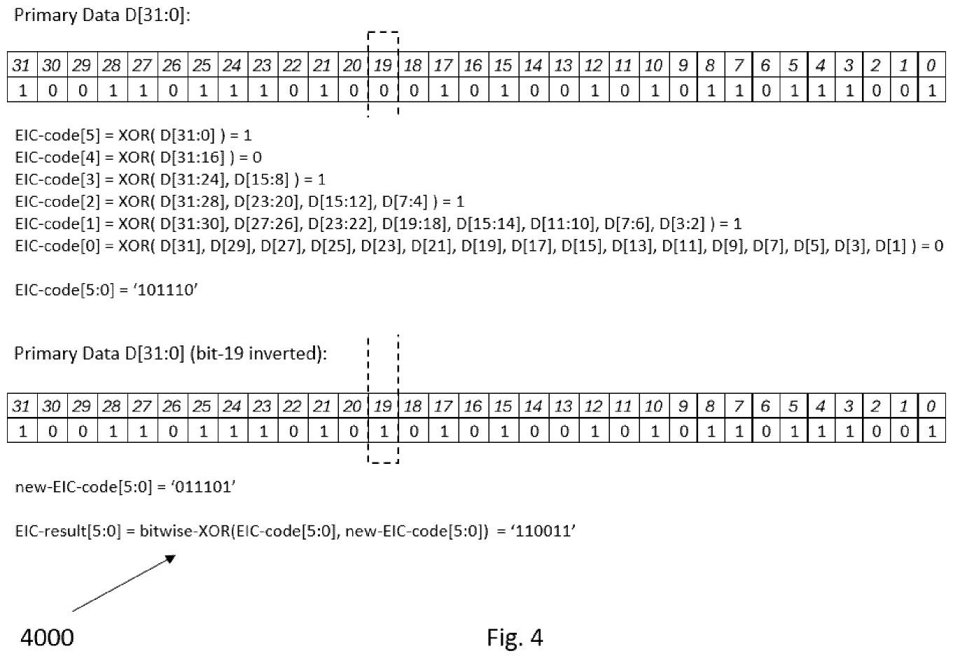

FIG. 4 illustrates an example (reference numeral 4000) demonstrating the generation of a 6-bit Error Index Code (EIC) for a 32-bit primary data stream. The figure details the subsequent process for identifying the location of a bit error within the data. The exemplary 32-bit primary data, D[31:0], represented in binary format, is 0b10011011101000101001010110111001. Utilizing the EIC Method 3000, the redundancy bits EIC-code[5:0] are generated as follows:
1. EIC-code[5]: An XOR operation is performed on all bits of the primary data: D[31:0], resulting in a binary value of ‘1’.
2. EIC-code [4]: An XOR operation is performed on the upper 16 bits of the primary data: D[31:16], resulting in a binary result of ‘0’.
3. EIC-code[3]: An XOR operation is performed on two segments of the primary data: D[31:24] and D[15:8], resulting in a binary value of ‘1’.
4. EIC-code[2]: An XOR operation is performed on four segments of the primary data: D[31:28], D[23:20], D[15:12], and D[7:4], resulting in a binary output of ‘1’.
5. EIC-code [1]: An XOR operation is performed on eight segments of the primary data: D[31:30], D[27:26], D[23:22], D[19:18], D[15:14], D[11:10], D[7:6], and D[3:2], resulting in a binary result of ‘1’.
6. EIC-code[0]: An XOR operation is performed on the bits located at odd indices within the primary data, specifically D[31], D[29], D[27], D[25], D[23], D [21], D[19], D[17], D[15], D[13], D[11], D[9], D[7], D[5], D[3], and D[1], resulting in a binary value of ‘0’

Therefore, the generated EIC data is represented as EIC-code[5:0]=0b101110.

Following a data error, as illustrated in FIG. 4 where the bit at index 19 is inverted from ‘0’ to ‘1’, resulting in the modified primary data D[31:0]=0b10011011101010101001010110111001. The EIC Method 3000 is re-applied. Repeating the XOR operations described previously (steps 1 through 6), a new EIC data, designated as new-EIC-code[5:0], is generated and determined to be 0b011101. Subsequently, a bitwise XOR operation is performed between the original EIC data (EIC-code[5:0]) and the newly generated EIC data (new-EIC-code[5:0]), yielding a result vector EIC-result[5:0]=0b110011. The presence of a ‘1’ in EIC-result[5] indicates the occurrence of an error within the primary data. Furthermore, bits EIC-result[4:0], possessing the binary value 0b10011, directly represent the index of the erroneous bit within the primary data, specifically identifying bit index 19 .

Generally, for any 2ⁿ bits primary data D[2ⁿ-1:0], The EIC Method 3000 generates an associated n+1 bits initial redundancy code, designated as EIC-code[n:0]. Both the primary data and the initial redundancy code are transmitted or stored together. Upon detection of a bit error within the primary data D[2ⁿ-1:0], the EIC Method 3000 is re-applied to generate a new n+1 bits redundancy code, designated as new-EIC-code[n:0]. A subsequent bitwise XOR operation between the initial redundancy code (EIC-code[n:0]) and the newly generated redundancy code (new-EIC-code[n: 0]) yields a result vector, designated as EIC-result[n:0]. In the absence of errors in the primary data, all bits of EIC-result[n:0] are ‘0’. A single error within the primary data results in EIC-result[n] being ‘1’, with the remaining bits (EIC-result[n-1:0]) directly indicating the index of the erroneous bit, and the corresponding bit in the primary data can be inverted when doing correction. The presence of two errors is indicated by a ‘0’ value for EIC-result[n], and at least one ‘1’ bit within EIC-result[n-1:0]. The Error Index Code (EIC) provides single-error correction and double-error detection (SECDED) capabilities. In instances where multiple errors are present within the primary data, EIC-result[n-1:0] represents the bitwise XOR of the indices corresponding to all erroneous bits.

To mitigate potential data errors within the initial redundancy code itself during transmission, processing or storage, an supplementary parity bit is generated from the initial redundancy code data via a XOR operation and transmitted, processed or stored alongside the primary data and the initial redundancy code. Upon detection of a bit error in the data stream (encompassing the primary data, the initial redundancy code, and the supplementary parity), verification of the initial redundancy code begins with assessment of the supplementary parity bit. If an error is detected within the initial redundancy code, then the primary data is considered error-free. Conversely, if no error is detected in the redundancy code, the primary data is analyzed for errors using the method as described in the previous paragraph. Upon detection of an error within the initial redundancy code, the initial redundancy code may be superseded by the newly generated redundancy code, and the supplementary parity bit is updated via the XOR operation result applied to the newly generated redundancy code. Following the inclusion of the parity bit, the Error Index Code (EIC) retains its single-error correction capability; however, its double-error detection functionality fails in a very rare scenario, when both errors occur within the redundancy code sequence (comprising the initial redundancy code and the extra parity bit), and specifically when the most significant bit of the initial redundancy code is inverted. To address this limitation, an additional bit is incorporated; this bit replicates the most significant bit of the initial redundancy code and functions in conjunction with the extra parity bit.

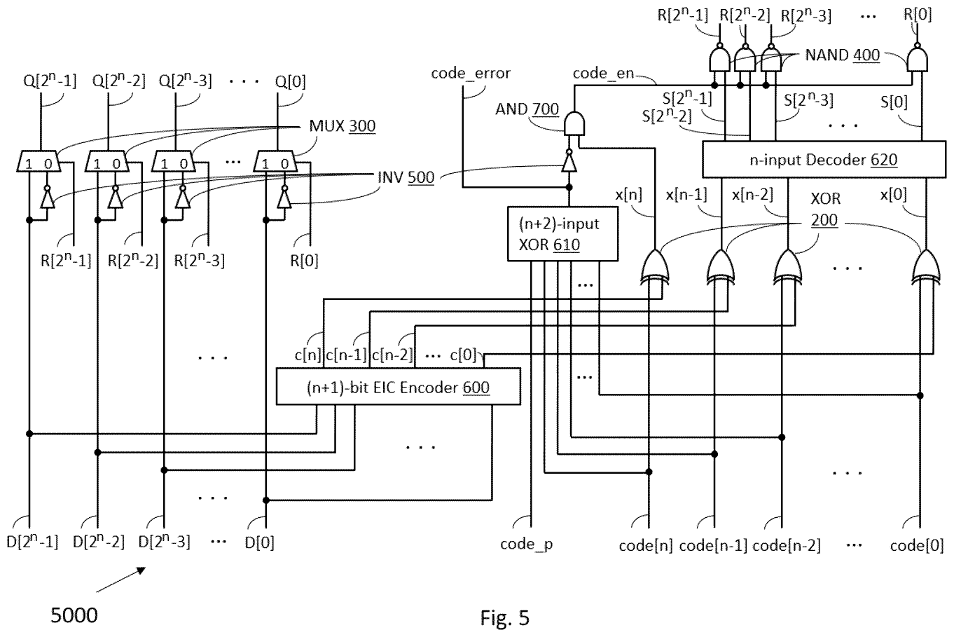

FIG. 5 illustrates a block diagram (reference numeral 5000) depicting a single-error correction circuit implementing an Error Index Code (EIC) methodology, representative of one embodiment of the present invention. The circuit comprises several functional blocks including an (n+1)-bit EIC encoder (reference numeral 600), an (n+2)-input XOR gate (reference numeral 610), an n-input decoder (reference numeral 620), an AND gate (reference numeral 700), multiple two-input XOR gates (reference numeral 200), multiplexer gates (reference numeral 300), NAND gates (reference numeral 400), and inverter gates (reference numeral 500).

The (n+1)-bit EIC encoder (600) processes the input primary data stream D[2ⁿ-1:0] to generate redundancy bits, denoted as c[n:0]. The (n+2)-input XOR gate (610) performs a logical XOR operation on the received redundancy code, code[n:0], and the extra parity bit, code_p, producing a resultant signal, designated code_error. The code_error signal asserts to a logic high (‘1’) when a discrepancy is detected between the redundancy code and the extra parity bit, indicating an error within the redundancy code and the extra parity bit detected; otherwise, it asserts to a logic low (‘0’).

Upon assertion of code_error as high (‘1’), the inverter (500) inverts this signal, generating a logic low (‘0’) output. This inverted signal then activates an AND gate (700), producing a logic low (‘0’) signal, designated code_en. Concurrently, the NAND gates (400) generate signals R[2ⁿ-1:0], all asserted to a logic high (‘1’). The multiplexer gates (300) subsequently pass the primary data input D[2ⁿ-1:0] directly through to the output Q[2ⁿ-1:0].

The multiple two-input XOR gates (200) operate on corresponding bits of the generated redundancy bit c[n:0] and the received redundancy code bit code[n:0], producing signals x[n:0]. A logic high (‘1’) assertion on x[n] indicates an error within the primary data input D[2ⁿ-1:0]; conversely, a logic low (‘0’) assertion signifies agreement and absence of detected single bit errors. The signals x[n-1:0] serve as inputs to the n-input decoder (620), which generates output signals S[2ⁿ-1:0]. The decoder's output is characterized by a single signal, S[m], where 0≤m≤2−1, asserting to a logic high (‘1’), thereby identifying the index ‘m’ of the error bit.

When x[n] asserts as low (‘0’), the AND gate (700) maintains a low code_en signal, and the NAND gates (400) generate signals R[2ⁿ-1:0], all at logic high (‘1’). The multiplexer gates (300) then pass the primary data input D[2ⁿ-1:0] directly to the output Q[2ⁿ-1:0]. When x[n] asserts as high (‘1’) and code_error is low (‘0’), the code_en signal transitions to a logic high (‘1’). The NAND gates (400) then invert the signals S[2ⁿ-1:0], resulting in only one output, R[m], asserting to a logic low (‘0’). The multiplexer gates (300) selectively invert D[m] while passing all other data bits directly.

This process effectively corrects the single bit error present within the input data sequence (the primary data, the received redundancy code, and an extra parity bit). The code_en and code_error signals can be utilized as update signals for updating the primary data, the received redundancy code, and the extra parity bit; specifically, when the code_en signal is high (‘1’) and the code_error signal is low (‘0’), the primary data can be updated with Q [2ⁿ-1:0]; and when the code_error signal is high (‘1’), the redundancy code can be updated with the generated redundancy bit c[n:0] and the extra parity bit can be updated via an XOR operation on c[n:0].

While the disclosure utilizes XOR operations, functionally equivalent XNOR operations may also be implemented without exceeding the claimed scope of this invention.

In this detailed description, various embodiments or examples of the present invention may be implemented in numerous ways. A detailed description of one or more embodiments of the invention is provided above along with accompanying figures that illustrate the principles of the invention. The invention is described in connection with such embodiments, but the invention is not limited to any embodiment. Numerous modifications and variations within the scope of the present invention are possible. The scope of the invention is limited only by the claims, and the invention encompasses numerous alternatives, modifications, and equivalents. Numerous specific details are set forth in the description to provide a thorough understanding of the invention. These details are provided for the purpose of example, and the invention may be practiced according to the claims without some or all of these specific details. For the purpose of clarity, technical material that is known in the technical fields related to the invention has not been described in detail so that the invention is not unnecessarily obscured. The present invention is defined by the appended claims.

1. An (n+1)-bit Error Index Code (EIC) encoder which processes a 2ⁿ-bit primary data input to generate a (n+1)-bit redundancy code, comprising: two n-bit EIC encoders and n instances of two-input XOR gates, wherein n≥2.
Each n-bit EIC encoder processes half of the primary data input to produce a n-bit redundancy code.
The (n+1)-bit redundancy code is generated via the following operations: The most significant bit is derived from an XOR operation between the most significant bits of the redundant codes produced by the two n-bit EIC encoders; the second most significant bit corresponds directly to the most significant bit of the redundant code generated by the n-bit EIC encoder processing the upper half of the primary data input; and the remaining bits are derived from XOR operations between corresponding index bits of the redundant codes generated by the two n-bit EIC encoders.

2. The (n+1)-bit Error Index Code (EIC) encoder of claim 1, wherein for n≥3, said n-bit EIC encoder is constructed recursively utilizing two (n−1)-bit EIC encoders and their corresponding n−1 XOR gates.

3. The (n+1)-bit Error Index Code (EIC) encoder of claim 1, wherein the 2-bit EIC encoder processes a 2-bit primary data input to generate a 2-bit redundancy code, comprising a single two-input XOR gate.
The 2-bit redundancy code is generated via the following operations: The most significant bit is derived from an XOR operation between the two primary data bits; and the least significant bit corresponds directly to the most significant bit of the 2-bit primary data input.

4. The (n+1)-bit Error Index Code (EIC) encoder of claim 1, further comprises the implementation of functionally equivalent XNOR gates in addition to XOR gates.

5. An Error Index Code (EIC) method processes a 2ⁿ-bit primary data stream and generates n+1 bits of redundancy code. The bit indices sequence of the primary data is defined from 0 to 2ⁿ−1 (right to left). The method operates as follows:
The most significant bit of the redundancy code is derived from an exclusive OR (XOR) operation applied to all bits of the primary data. For each redundancy bit at index m, where 0≤m≤n−1 , the primary data is evenly partitioned into 2^{n-m} sections, sequentially numbered from 0 to 2^{n-m}−1 (right-to-left). The resulting redundancy bit is then generated by performing an exclusive OR (XOR) operation on all bits within the odd-numbered sections of this partition.

6. The Error Index Code (EIC) method of claim 5 comprises applying the XOR operation to even-numbered sections of the partition when defining bit indices in reversed sequence.

7. The Error Index Code (EIC) method of claim 5, further comprises the implementation of functionally equivalent XNOR operations in addition to XOR operations.

8. The Error Index Code (EIC) method of claim 5, further comprising the steps of:
Said redundancy code is concurrently transmitted, processed or stored with the primary data stream.

9. The Error Index Code (EIC) method of claim 5, further comprising the steps of:
A supplementary parity bit is generated through an XOR operation applied to the data within said redundancy code. This parity bit is concurrently transmitted, processed or stored with both the primary data stream and said redundancy code.

10. The Error Index Code (EIC) method of claim 9, further comprising the following steps for single-bit error detection and correction:
Verification of said redundancy code commences with an assessment of said parity bit.
If an error is detected within said redundancy code, the primary data is determined to be error-free.
If no error is detected within said redundancy code, the EIC method of claim 5 is re-executed to generate a new redundancy code from the primary data. A subsequent bitwise XOR operation between said redundancy code and the newly generated redundancy code produces a result vector. If all bits within the result vector register as ‘0’, the primary data is determined to be error-free. If the most significant bit of the result vector is high (‘1’), the remaining bits of the result vector directly indicate the index of the erroneous bit, and the corresponding bit in the primary data is inverted. If the most significant bit of the result vector is low (‘0’) and at least one ‘1’ bit within the remaining bits of the result vector, the presence of two errors in the primary data is indicated.
Upon detection of an error within said redundancy code, said redundancy code can be superseded by the newly generated redundancy code, and said parity bit is updated via the XOR operation result applied to the newly generated redundancy code.

11. An error correction circuit implementing the Error Index Code (EIC) methodology of claim 10, comprising: at least an (n+1)-bit EIC encoder, a (n+2)-input XOR gate, an n-input decoder, and multiple 2-input XOR gates.
The (n+1)-bit EIC encoder processes the primary data inputs to generate new redundancy code signals.
The (n+2)-input XOR gate performs a logical XOR operation on said redundancy code signals and said parity bit signal to detect potential bit errors within said redundancy code signals and said parity bit signal.
If an error is detected in said redundancy code signals and said parity bit signal, the primary data inputs are directly output.
Otherwise, the 2-input XOR gates perform a bitwise XOR operation between the newly generated redundancy code signals and said redundancy code signals, generating a result vector signal. The most significant bit of this result vector signal indicates the presence of a bit error in the primary data inputs, while the n-input decoder utilizes the remaining bits of the vector signal to generate an error bit index signal. Upon detection of a bit error in the primary data inputs, the error bit index signal inverts the corresponding bit within the primary data inputs; otherwise, all bits within the primary data inputs are directly output.
